(19) United States
(12) Patent Application Publication
(10) Pub. No.: US 2025/0247079 A1
(43) Pub. Date: Jul. 31, 2025

(54) INDUCTOR INTEGRATED ACOUSTIC WAVE DEVICE

(71) Applicant: Skyworks Global Pte. Ltd., Singapore (SG)

(72) Inventors: Stefan Bader, Fort Collins, CO (US); Kwang Jae Shin, Yongin-si (KR); Atsushi Takano, Kadoma -Shi (JP); Jae Hyung Lee, Seoul (KR); Nan Wu, Irvine, CA (US); Yiliu Wang, Irvine, CA (US); Alexandre Augusto Shirakawa, Cardiff by the Sea, CA (US)

(21) Appl. No.: 19/034,382

(22) Filed: Jan. 22, 2025

Related U.S. Application Data
(60) Provisional application No. 63/625,033, filed on Jan. 25, 2024.
(60) Provisional application No. 63/625,021, filed on Jan. 25, 2024.

(51) Int. Cl. H03H 9/54; H03H 3/02; H03H 9/10; H03H 9/17; H03H 9/56

(52) U.S. Cl. CPC H03H 9/542; H03H 3/02; H03H 9/105; H03H 9/173; H03H 9/564; H03H 9/547

(57) ABSTRACT

An acoustic wave device is disclosed. The acoustic wave device can include a substrate, a lid, a resonator, and an inductor. The lid has a first side facing the substrate and a second side opposite the first side. The lid is coupled to the substrate. The resonator is positioned between the substrate and the lid. The inductor is formed with the lid. The inductor is at least partially positioned over a portion of the resonator.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/625,033, filed Jan. 25, 2024, titled “INDUCTOR INTEGRATED ACOUSTIC WAVE DEVICE,” and U.S. Provisional Patent Application No. 63/625,021, filed January 253, 2024, titled “ACOUSTIC WAVE DEVICE WITH INDUCTOR,” are hereby incorporated by reference under 37 CFR 1.57 in their entirety.

### BACKGROUND

### Technical Field

Embodiments of this disclosure relate to acoustic wave devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A bulk acoustic wave resonator can include a set of metal electrodes deposited on opposite surfaces of a piezoelectric material, generating a bulk acoustic wave within the volume of the piezoelectric material. The interaction between the electrodes and the piezoelectric material results in the formation and propagation of a bulk acoustic wave.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an acoustic wave device including: a substrate; a lid having a first side facing the substrate and a second side opposite the first side, the lid coupled to the substrate; a resonator positioned between the substrate and the lid; and an inductor formed with the lid, the inductor at least partially positioned over a portion of the resonator.

In some embodiments, the techniques described herein relate to an acoustic wave device wherein the substrate and the lid are coupled by a seal ring, the substrate, the lid, and the seal ring together define a hermetic cavity in which the resonator is positioned.

In some embodiments, the techniques described herein relate to an acoustic wave device wherein the resonator is a bulk acoustic wave resonator.

In some embodiments, the techniques described herein relate to an acoustic wave device wherein the inductor is a spiral inductor formed on the first side of the lid.

In some embodiments, the techniques described herein relate to an acoustic wave device wherein the inductor is a spiral inductor formed on the second side of the lid.

In some embodiments, the techniques described herein relate to an acoustic wave device further including an overcoat layer over the inductor.

In some embodiments, the techniques described herein relate to an acoustic wave device wherein the overcoat layer includes a low dielectric loss polymeric material that has a dielectric loss less than 0.01.

In some embodiments, the techniques described herein relate to an acoustic wave device wherein the low dielectric loss polymeric material is polyimide, fluoropolymer, polyphenylene sulfide, or benzocyclobutene.

In some embodiments, the techniques described herein relate to an acoustic wave device wherein the overcoat layer includes titanium oxide, calcium titanate, strontium titanate, or barium strontium titanate blended with the low dielectric loss polymeric material that defines a composite material and the composite material has a dielectric constant greater than 5.

In some embodiments, the techniques described herein relate to an acoustic wave device wherein the inductor includes a first portion formed on the first side of the lid, a second portion formed on the second side of the lid, and a third portion formed through a thickness of the lid.

In some embodiments, the techniques described herein relate to an acoustic wave device further including a second inductor formed with the substrate.

In some embodiments, the techniques described herein relate to an acoustic wave device further including a shield layer positioned between the second inductor and the resonator.

In some embodiments, the techniques described herein relate to an acoustic wave device wherein the substrate and the lid are spaced apart in a range between 5 microns and 50 microns.

In some embodiments, the techniques described herein relate to an acoustic wave device wherein a thickness of the lid is in a range between 30 microns and 150 microns.

In some embodiments, the techniques described herein relate to an acoustic wave device wherein the inductor includes copper, aluminum, gold, silver, tungsten, molybdenum, ruthenium, iridium, or platinum.

In some embodiments, the techniques described herein relate to an acoustic wave device wherein the lid includes silicon, gallium arsenide, silicon carbide, sapphire, quartz, glass, ceramics, polymers, oxides, or nitrides.

In some embodiments, the techniques described herein relate to an acoustic wave device further including an interconnect that connects the substrate and the inductor.

In some embodiments, the techniques described herein relate to an acoustic wave device wherein the substrate includes a terminal configured to electrically connect the acoustic wave device to an external device or a circuit board.

In some aspects, the techniques described herein relate to a method of forming an acoustic wave device, the method including: providing a resonator on a substrate; and coupling an inductor integrated lid to the substrate such that the resonator is positioned between the substrate and the inductor integrated lid, the inductor integrated lid having a first side facing the substrate and a second side opposite the first side.

In some embodiments, the techniques described herein relate to a method further including forming an inductor in the inductor integrated lid, wherein at least a portion of the inductor is disposed on the first side or the second side.

In some embodiments, the techniques described herein relate to a method wherein the inductor includes a first portion formed on the first side of the inductor integrated lid, a second portion formed on the second side of the inductor integrated lid, and a third portion formed through a thickness of the inductor integrated lid.

In some aspects, the techniques described herein relate to an acoustic wave device including: a substrate; an inductor integrated lid having a first side facing the substrate, a second side opposite the first side, and an inductor, the inductor integrated lid coupled to the substrate; and a resonator positioned between the substrate and the inductor integrated lid, the inductor at least partially positioned over a portion of the resonator.

In some aspects, the techniques described herein relate to an acoustic wave device including: a substrate having a first side and a second side opposite the first side; a resonator over the first side of the substrate; and an inductor formed with the substrate, at least a portion of the inductor disposed on the second side of the substrate.

In some embodiments, the techniques described herein relate to an acoustic wave device wherein the resonator is a bulk acoustic wave resonator.

In some embodiments, the techniques described herein relate to an acoustic wave device wherein the inductor is a spiral inductor formed on the second side of the substrate.

In some embodiments, the techniques described herein relate to an acoustic wave device further including a shield layer positioned between the inductor and the resonator.

In some embodiments, the techniques described herein relate to an acoustic wave device wherein the shield layer is a metal layer buried in an oxide layer between the substrate and the resonator.

In some embodiments, the techniques described herein relate to an acoustic wave device further including an overcoat layer over the inductor on the second side of the substrate.

In some embodiments, the techniques described herein relate to an acoustic wave device wherein the overcoat layer includes a low dielectric loss polymeric material that has a dielectric loss less than 0.01.

In some embodiments, the techniques described herein relate to an acoustic wave device wherein the low dielectric loss polymeric material is polyimide, fluoropolymer, polyphenylene sulfide, or benzocyclobutene.

In some embodiments, the techniques described herein relate to an acoustic wave device wherein the overcoat layer includes titanium oxide, calcium titanate, strontium titanate, or barium strontium titanate blended with the low dielectric loss polymeric material that defines a composite material and the composite material has a dielectric constant greater than 5.

In some embodiments, the techniques described herein relate to an acoustic wave device wherein the inductor includes a first portion formed on the first side of the substrate, a second portion formed on the second side of the substrate, and a third portion formed through a thickness of the substrate.

In some embodiments, the techniques described herein relate to an acoustic wave device wherein the first portion of the inductor includes a buried metal buried in an oxide layer between the substrate and the resonator.

In some embodiments, the techniques described herein relate to an acoustic wave device wherein the inductor includes copper, aluminum, gold, silver, tungsten, molybdenum, ruthenium, iridium, or platinum.

In some embodiments, the techniques described herein relate to an acoustic wave device wherein the substrate includes silicon, gallium arsenide, silicon carbide, sapphire, quartz, glass, ceramics, polymers, oxides, or nitrides.

In some embodiments, the techniques described herein relate to an acoustic wave device wherein the substrate includes a terminal configured to electrically connect the acoustic wave device to an external device or a circuit board.

In some embodiments, the techniques described herein relate to an acoustic wave device further including a lid coupled to the substrate.

In some embodiments, the techniques described herein relate to an acoustic wave device further including a second inductor formed with the lid.

In some embodiments, the techniques described herein relate to an acoustic wave device further including an interconnect that connects the substrate and the second inductor.

In some embodiments, the techniques described herein relate to an acoustic wave device wherein the substrate and the lid are coupled by a seal ring, the substrate, the lid, and the seal ring together define a hermetic cavity in which the resonator is positioned.

In some aspects, the techniques described herein relate to a method of forming an acoustic wave device, the method including: forming an inductor with a substrate having a first side and a second side opposite the first side, at least a portion of the inductor disposed on the second side of the substrate; and providing a resonator on the first side of the substrate, at least a portion of the resonator positioned over the inductor.

In some embodiments, the techniques described herein relate to a method further including providing an overcoat layer over the inductor on the second side of the substrate wherein the inductor is a spiral inductor formed on the second side of the substrate.

In some embodiments, the techniques described herein relate to a method wherein the inductor includes a first portion formed on the first side of the substrate, a second portion formed on the second side of the substrate, and a third portion formed through a thickness of the substrate.

In some aspects, the techniques described herein relate to an acoustic wave device including: an inductor integrated substrate including an inductor, the inductor integrated substrate having a first side and a second side opposite the first side; and a resonator over the first side of the inductor integrated substrate, at least a portion of the inductor disposed on the second side of the inductor integrated substrate.

The present disclosure relates to U.S. Patent Application No. [Attorney Docket SKYWRKS.1513A2], titled “ACOUSTIC WAVE DEVICE WITH INDUCTOR,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of an acoustic wave device according to an embodiment.

FIG. 1B is a bottom plan view of the acoustic wave device of FIG. 1A.

FIG. 2A is a schematic cross-sectional side view of an acoustic wave device according to an embodiment.

FIG. 2B is a bottom plan view of an inductor formed on a lid of the acoustic wave device of FIG. 2A.

FIG. 3A is a schematic cross-sectional side view of an acoustic wave device according to an embodiment.

FIG. 3B is a bottom plan view of the acoustic wave device of FIG. 3A.

FIG. 4A is a schematic cross-sectional side view of an acoustic wave device according to an embodiment.

FIG. 4B is a top plan view of an inductor formed on a lid of the acoustic wave device of FIG. 2A.

FIG. 5A is a schematic cross-sectional side view of an acoustic wave device according to an embodiment.

FIG. 5B is a top plan view of an inductor formed with a lid of the acoustic wave device of FIG. 5A.

FIG. 6A is a schematic cross-sectional side view of an acoustic wave device according to an embodiment.

FIG. 6B is a bottom plan view of an inductor formed with a substrate of the acoustic wave device of FIG. 6A.

FIG. 7 is a schematic cross-sectional side view of an acoustic wave device according to an embodiment.

FIGS. 8A and 8B are plan views of three-dimensional (3D) inductors according to some embodiments.

FIG. 9 is a schematic diagram of an example of an acoustic wave ladder filter.

FIG. 10A is a schematic diagram of an example of a duplexer.

FIG. 10B is a schematic diagram of an example of a multiplexer.

FIG. 11 is a schematic block diagram of a module that includes an antenna switch and duplexers that include one or more bulk acoustic wave devices.

FIG. 12A is a schematic block diagram of a module that includes a power amplifier, a radio frequency switch, and duplexers that include one or more bulk acoustic wave devices.

FIG. 12B is a schematic block diagram of a module that includes a low noise amplifier, a radio frequency switch, and acoustic wave filters that include one or more bulk acoustic wave devices.

FIG. 13 is a schematic block diagram of a module that includes a power amplifier, a radio frequency switch, a duplexer that includes one or more bulk acoustic wave devices.

FIG. 14A is a schematic block diagram of a wireless communication device that includes filters that include one or more bulk acoustic wave devices.

FIG. 14B is a schematic block diagram of another wireless communication device that includes filters that include one or more bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with bulk acoustic wave (BAW) devices. A film acoustic wave resonator (FBAR) and a BAW solidly mounted resonator (SMR) are examples of BAW devices. An acoustic wave filter can be implemented with surface acoustic wave (SAW) devices. A temperature compensated surface acoustic wave (TC-SAW) device and a multi-layer piezoelectric substrate surface acoustic wave (MPS-SAW) device are examples of SAW devices.

Integration of inductors and capacitors can be important to tailor performance of an acoustic wave device, such as an acoustic wave filter. The inductors and the capacitors can enhance various aspects of the acoustic wave filter, including resonator characteristics, rejection of unwanted bands, filter steepness, and phase-shifting capabilities. Inductors can be employed to enhance the performance of resonators, specifically by increasing the resonator coupling coefficient Kt2 and/or improving return loss (RL). By integrating inductors in series with shear horizontal (SH) resonators, rejection for multiple bands can be enhanced. For instance, in the transmit (Tx) band and the carrier aggregation (CA) band, inductors effectively contribute to rejection capabilities. In the presence of harmonic bands, inductors can mitigate unwanted frequencies, contributing to a cleaner and more selective filter response. Parallel integration of inductors with square extensional (SE) resonators can serve to elevate the fundamental frequency (Fp) of the resonator, and/or to introduce an additional notch at a frequency significantly lower than the filter passband. This configuration can be particularly useful for achieving notch filtering capabilities without compromising the integrity of the desired passband frequencies.

In phase shifters, inductors can be employed for mitigating out-of-band (OOB) phase spreading. Placing an inductor in parallel with a series resonator can help alleviate loading in the carrier aggregation (CA) band. Also, incorporating inductor-capacitor (LC) networks in front of the filter can facilitate the design of multiplexers (MPX), allowing for precise control of the filter response characteristics. For applications like low-noise amplifiers (LNA) and antennas (ANT), self-matched filters can leverage inductors to achieve optimal impedance matching, enhancing overall system performance.

An inductor can be implemented with an acoustic wave device (e.g., a BAW device) as a surface mount device (SMD) component, or as embedded traces in a multi-chip module (MCM) separate from the device die. Because such SMD and MCM inductor are provided separately, they can significantly increase the overall size. With the increased demand for size reduction of the BAW devices, the SMD and MCM implementations of inductors may not be ideal.

Various embodiments disclosed herein relate to acoustic wave devices (e.g., an acoustic wave filter) with an inductor. In some embodiments, the inductor can be incorporated in a chip-scale package (CSP) bulk acoustic wave (BAW) die without significantly increasing the BAW die size. In some embodiments, an inductor can be integrated with a substrate to define an inductor integrated substrate that can support one or more acoustic wave resonators. In some embodiments, an inductor can be integrated with a lid to define an inductor integrated lid. The lid can be coupled to a substrate to package one or more acoustic wave resonators.

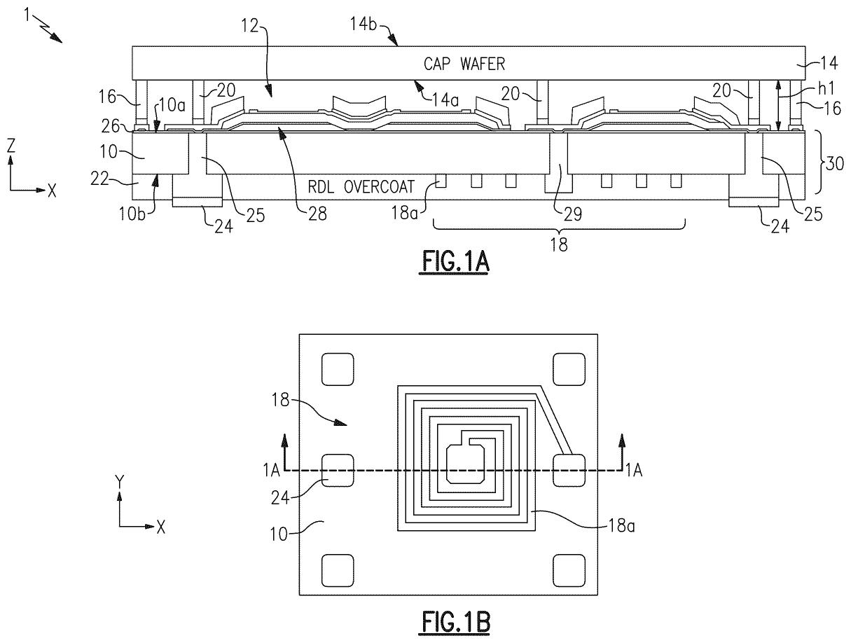

FIG. 1A is a schematic cross-sectional side view of an acoustic wave device 1 according to an embodiment. FIG. 1B is a bottom plan view of the acoustic wave device 1 of FIG. 1A. At least a component is shown transparent in FIG. 1B to show internal components. The acoustic wave device 1 can be an acoustic wave filter such as a chip-scale package (CSP) bulk acoustic wave (BAW) filter die. The acoustic wave device 1 can include a substrate 10, an acoustic wave resonator 12, a lid 14 coupled to the substrate by way of a coupler (e.g., a seal ring 16), and an inductor 18 formed with the substrate 10. The acoustic wave device 1 can also include an interconnect structure 20 that extends between the substrate 10 and the lid 14, an overcoat layer 22 that is disposed at least partially over the inductor 18, and a terminal 24 that is configured to electrically connect the acoustic wave device 1 to an external device or a circuit board (not shown).

The substrate 10 has a first side 10a and a second side 10b opposite the first side 10a. In some embodiments, the substrate 10 can be a semiconductor substrate such as a silicon substrate, a gallium arsenide substrate, or a silicon carbide substrate. In some other embodiments, the substrate 10 can be a sapphire substrate or a quartz substrate. The substrate 10 can be part of a support structure that includes, for example, the substrate 10, a trap rich layer (not shown), a passivation layer 26, or one or more intermediate layers therebetween (not shown). The substrate 10 can also include a via 25 that extends at least partially through a thickness of the substrate 10.

The illustrated embodiments of FIG. 1A shows a bulk acoustic wave (BAW) resonator as the resonator 12. In some embodiments, the acoustic wave resonator 12 can be any other suitable types of resonators, such as a surface acoustic wave resonator. A cavity 28 can be formed between the substrate 10 and the resonator 12. The cavity can be an air cavity and the resonator 12 can be a film bulk acoustic wave resonator (FBAR). In some other embodiments, there can be a solid acoustic mirror and the resonator 12 can be a BAW solidly mounted resonator (SMR).

The acoustic wave device 1 can include any suitable number of resonators 12. For example, a plurality of resonators of the acoustic wave device 1 can be coupled to define an acoustic wave ladder filter. In some embodiments, the plurality of resonators can be coupled through a lateral interconnect, such as a conductive trace.

The lid 14 can include any suitable material. For example, the lid 14 can include silicon, gallium arsenide, silicon carbide, sapphire, quartz, glass, ceramics, polymers, oxides, or nitrides. In some embodiments, the lid 14 can be a singulated cap wafer. The lid 14 has a first side 14a and a second side 14b opposite the first side 14a. The first side 14a of the lid 14 can be coupled to the substrate 10 by way of the seal ring 16. In some embodiments, the substrate 10, the lid 14, and the seal ring 16 can together define a cavity in which the resonator 12 is positioned. For example, the cavity can be a hermetically sealed cavity or a hermetic cavity. In some embodiments, the interconnect structure 20 can be an interconnect that electrically connects the substrate 10 and the lid 14, and be positioned in the cavity. In some embodiments, the interconnect structure 20 can function as a support structure for supporting the lid 14. For example, the interconnect structure 20 can be a metal post or pillar, such as a copper pillar. A spacing between the substrate 10 and the lid 14 has a height h1. In some embodiments, the height h1 can be defined by a height of the seal ring 16. The substrate 10 and the lid 14 can be sufficiently distanced for desired operation of the resonator 12.

The inductor 18 can be formed on the second side 10b of the substrate 10. The inductor 18 can be a spiral inductor that includes a conductive trace 18a spirally formed on the second side 10b of the substrate 10. The spiral inductor can function by forming a magnetic field as an electric current that flows through its coil, storing magnetic energy. This inductance property can be influenced by factors such as coil turns and dimensions (e.g., a length, a width, a thickness, or a spacing) of the inductor 18. In electronic circuits, the inductor's reactance can oppose current changes, which can be crucial in applications like filters and oscillators. In some embodiments, the inductor 18 can have an inductance in a range between 0.1 nano Henry (nH) and 4 nH, 0.2 nH and 4 nH, or 0.2 nH and 2.5 nH, for example. In some embodiments, the inductor 18 can be electrically coupled to the resonator 12 at least partially through a via 29 that extends through a thickness of the substrate 10. The inductor 18 can include any suitable conductive materials such as copper, aluminum, gold, silver, tungsten, molybdenum, ruthenium, iridium, or platinum. In some embodiments, the inductor 18 can be positioned at a location of the second side 10b of the substrate 10 so as to prevent or mitigate interference between the resonator 12 and the inductor 18. Because the inductor 18 is formed with the substrate 10, the substrate 10 and the inductor 18 can together define an inductor integrated substrate 30. In some embodiments, the inductor 18 can be integrally formed with the substrate 10. For example, the inductor 18 can be part of the substrate 10.

The overcoat layer 22 can be provided on the second side 10b of the substrate 10. The overcoat layer 22 can function as a passivation layer to protect the conductive trace 18a of the inductor 18 and/or as an insulator between neighboring lines of the conductive trace 18a. The overcoat layer 22 can include any suitable organic or dielectric material. For example, the overcoat layer 22 can include polyimide, fluoropolymer, silicon oxide, silicon nitride, polytetrafluoroethylene (PTFE), polyphenylene sulfide (e.g., fortron manufactured by Fortron Industries LLC), benzocyclobutene (BCB), SU8 (e.g., bisphenol A novolac epoxy dissolved in an organic solvent), or acrylate-based polymer. For example, the overcoat layer 22 can include a material that has a dielectric loss less than 0.015, less than 0.01, less than 0.0075, or less than 0.005. The overcoat layer 22 can include, for example, a low dielectric loss polymeric material. In some embodiments, the overcoat layer 22 can include a material (e.g., a ceramic) with a relatively high dielectric constant. For example, the overcoat layer 22 can include titanium oxide (e.g., titanium dioxide (TiO₂)), calcium titanate (e.g., CaTiO₃), strontium titanate (e.g., SrTiO₃), barium strontium titanate (e.g., Ba_{0.5}Sr_{0.5}TiO₃) or the like material. In some embodiments, the relatively high dielectric constant material can be blended with a polymer to define a composite material (e.g., a polymer-ceramic composite). The composite material can have a dielectric constant greater than 5, greater than 5.5, or greater than 6. In some embodiments, the overcoat layer 22 can be a redistribution layer (RDL) that includes electrical routings therein.

Using the relatively high dielectric constant material disclosed herein as the overcoat layer 22 can increase the inductance of the inductor 18 and may contribute to miniaturization of the acoustic wave device 1 and/or increase its bandwidth. A spin-on process can be used to form the relatively high dielectric constant materials, in some embodiments. The relatively high dielectric constant materials can be integrated into polymer matrices to form polymer-ceramic composites under certain circumstances, in some embodiments. For example, the relatively high dielectric constant materials can serve as fillers in polymer matrices. When a ceramic filler is used to form the polymer-ceramic composite, low ceramic fill fractions can still achieve materials with a significant composite dielectric constant.

The passivation layer 26 can include any suitable material. The passivation layer 26 can be a dielectric layer. In some embodiments, the passivation layer can include silicon oxide or silicon nitride. For example, the passivation layer 26 can be a silicon oxycarbide layer, a silicon dioxide layer, silicon nitride, silicon carbide, aluminum oxide, beryllium oxide, or any other suitable dielectric material and/or passivation layer.

FIGS. 1A and 1B illustrate that the inductor 18 is formed with the substrate 10. However, in some embodiments, the inductor 18 can be formed with the lid 14 in some other embodiments.

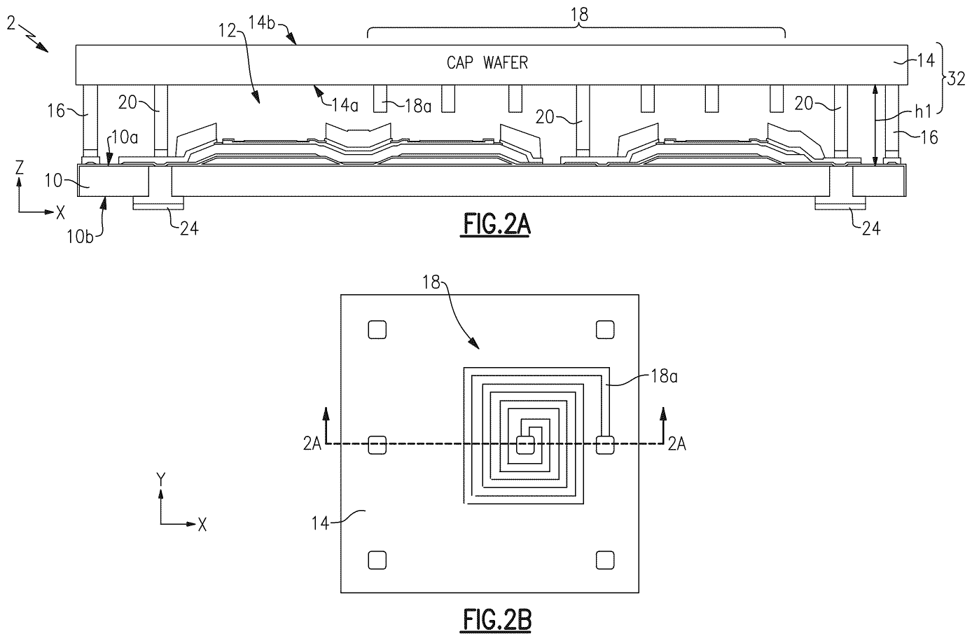

FIG. 2A is a schematic cross-sectional side view of an acoustic wave device 2 according to an embodiment. FIG. 2B is a bottom plan view of an inductor 18 formed on a lid 14 of the acoustic wave device 2 of FIG. 2A. Unless otherwise noted, the components of the acoustic wave device 2 shown in FIGS. 2A and 2B may be structurally and/or functionally the same as or generally similar to like components of the acoustic wave device 1 of FIGS. 1A and 1B. The acoustic wave device 2 can include a substrate 10, an acoustic wave resonator 12, a lid 14 coupled to the substrate by way of a coupler (e.g., a seal ring 16), and an inductor 18 formed with the lid 14. The acoustic wave device 2 can also include an interconnect structure 20 that extends between the substrate 10 and the lid 14, and a terminal 24 that is configured to electrically connect the acoustic wave device 2 to an external device or a circuit board (not shown).

The inductor 18 can be formed on the first side 14a of the lid 14. The inductor 18 can be a spiral inductor that includes a conductive trace 18a spirally formed on the first side 14a of the lid 14. In some embodiments, the inductor 18 can be electrically coupled to the resonator 12 at least partially through the interconnect structure 20. The inductor 18 can include any suitable conductive materials such as copper, aluminum, gold, silver, tungsten, or platinum. In some embodiments, the inductor 18 can be positioned at a location of the first side 14a of the lid 14 so as to prevent or mitigate interference between the resonator 12 and the inductor 18. Because the inductor 18 is formed with the lid 14, the lid 14 and the inductor 18 can together define an inductor integrated lid 32. In some embodiments, the inductor 18 can be integrally formed with the lid 14. For example, the inductor 18 can be part of the lid 14 or be formed on the first side 14a of the lid 14.

A spacing between the substrate 10 and the lid 14 has a height h1. In some embodiments, the height h1 can be defined by a height of the seal ring 16. The substrate 10 and the lid 14 can be sufficiently distanced so as to prevent or mitigate interference between the resonator 12 and the inductor 18. In some embodiments, the height h1 and/or a thickness of the inductor 18 can be selected such that the distance between the resonator and the inductor 18 is at least 5 microns. For example, the distance between the resonator 12 and the inductor 18 can be in a range between 5 microns and 25 microns, 10 microns and 25 microns, 5 microns and 20 microns, or 10 microns and 20 microns. In some embodiments, the height h1 between the substrate 10 and the lid 14 can be in a range between 5 microns and 50 microns, 10 microns and 50 microns, or 10 microns and 40 microns.

A distance between the resonator 12 and the inductor 18 can relate to the spacing between the substrate 10 and the lid 14 which can be adjusted relatively easily in the acoustic wave device 2. However, with the inductor integrated substrate 30 of acoustic device 1 shown in FIGS. 1A and 1B, providing a sufficient distance between the inductor 18 and the resonator 12 may be challenging. For example, the inductor 18 may be positioned within 75 microns from the resonator 12 in some design configurations. In order to prevent or mitigate interference between the resonator 12 and the inductor 18, a shield may be provided between the resonator 12 and the inductor 18.

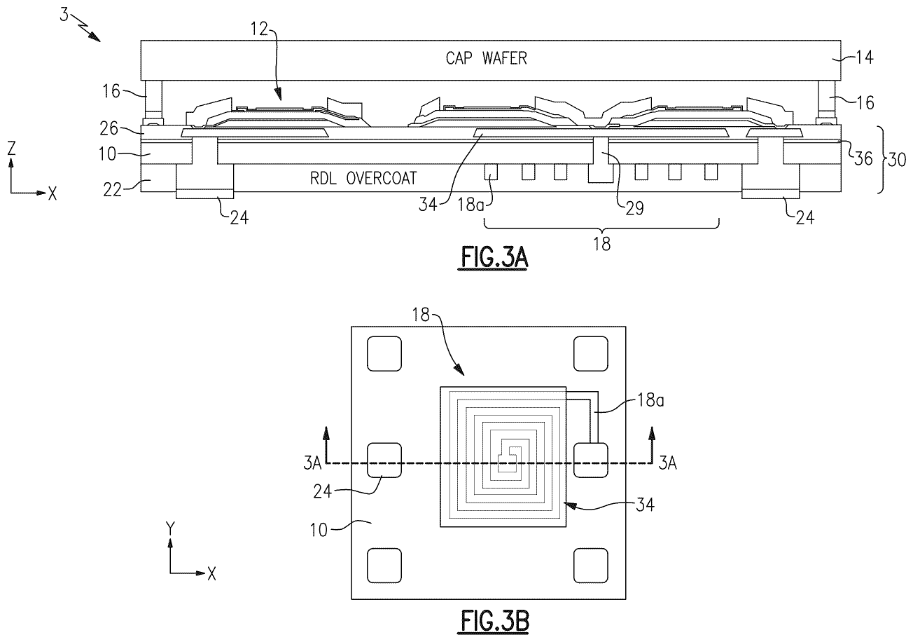

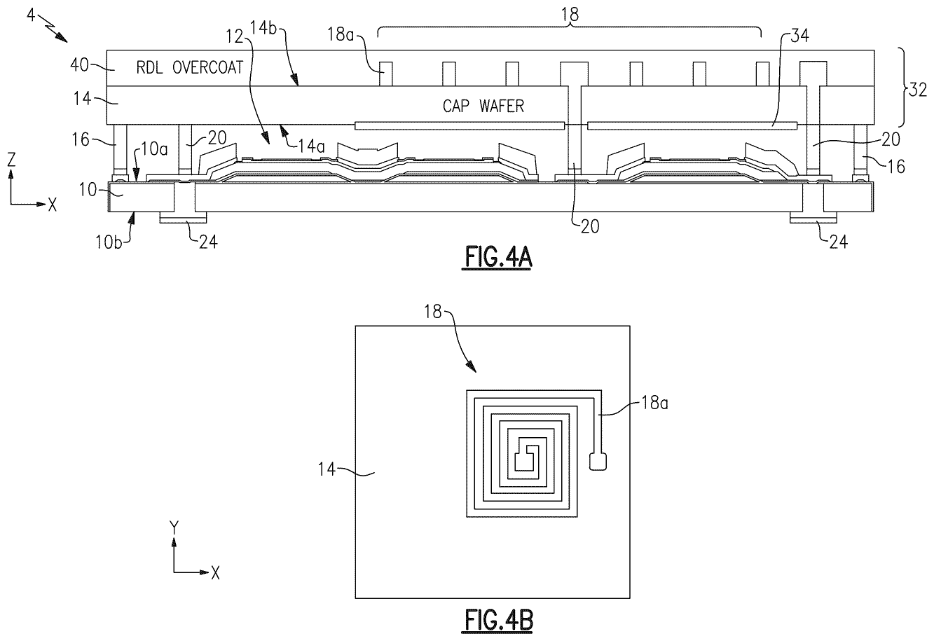

FIG. 3A is a schematic cross-sectional side view of an acoustic wave device 3 according to an embodiment. FIG. 3B is a bottom plan view of the acoustic wave device 3 of FIG. 3A. At least a component is shown transparent in FIG. 3B to show internal components. Unless otherwise noted, the components of the acoustic wave device 3 shown in FIGS. 3A and 3B may be structurally and/or functionally the same as or generally similar to like components of the acoustic wave device 1 of FIGS. 1A and 1B.

The acoustic wave device 3 can include a shield layer 34 between the resonator 12 and the inductor 18. The shield layer 34 can be a metal layer disposed at least partially in (e.g., completely buried in) the passivation layer 26. In some embodiments, the passivation layer 26 can be provided in a multi-step process. For example, the shield layer 34 can be provided on a thin layer of the passivation layer 26 that is provided over the substrate 10, and passivation material can be provided over the shield layer 34 to bury the shield layer 34 in the passivation layer 26. The shield layer 34 can be provided over a region of the inductor 18 as shown in FIG. 3B. The shield layer 34 can include any suitable material. In some embodiments, the shield layer 36 can include aluminum, copper, gold, silver, nickel molybdenum, tungsten, ruthenium, iridium, chromium, or any metal alloy thereof. In some embodiments, the shield layer 36 can be floated or connected to other elements in the acoustic wave device 3 or to ground.

The acoustic wave device 3 shown in FIG. 3A also illustrates a trap rich layer 36. The trap rich layer 36 can be a polysilicon layer, an amorphous silicon layer, or the like. A via 29 that connects the inductor 18 and the shield layer 34 can extend at least partially through (e.g., completely through) thicknesses of the substrate 10, the trap rich layer 36, and the passivation layer 26.

The inductor integrated lid 32 shown in FIG. 2A includes the inductor formed on the first side 14a of the lid 14. However, in some embodiments, the inductor 18 can be formed on the second side 14b of the lid 14.

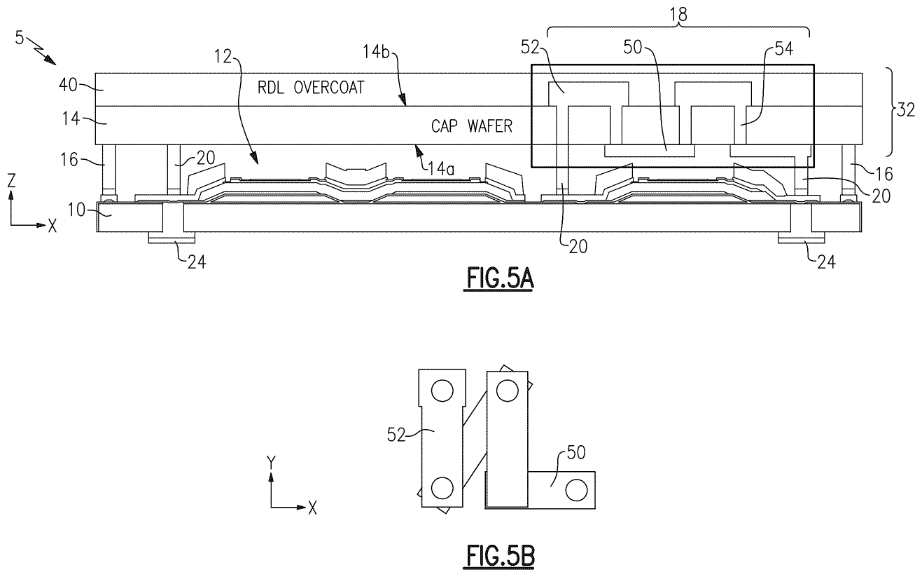

FIG. 4A is a schematic cross-sectional side view of an acoustic wave device 4 according to an embodiment. FIG. 4B is a top plan view of an inductor 18 formed on a lid 14 of the acoustic wave device 4 of FIG. 4A. Unless otherwise noted, the components of the acoustic wave device 4 shown in FIGS. 4A and 4B may be structurally and/or functionally the same as or generally similar to like components of the acoustic wave devices 1, 2, 3 of FIGS. 1A-3B.

In the acoustic wave device 4 shown in FIGS. 4A and 4B, the inductor 18 can be formed on the second side 14b of the lid 14. The inductor 18 can be a spiral inductor that includes a conductive trace 18a spirally formed on the second side 14b of the lid 14. In some embodiments, the inductor 18 can be electrically coupled to the resonator 12 at least partially through the interconnect structure 20. The inductor 18 can include any suitable conductive materials such as copper, aluminum, gold, silver, tungsten, or platinum. In some embodiments, the inductor 18 can be positioned at a location of the second side 10b of the substrate 10 so as to prevent or mitigate interference between the resonator 12 and the inductor 18. Because the inductor 18 is formed with the lid 14, the lid 14 and the inductor 18 can together define an inductor integrated lid 32.

An overcoat layer 40 can be provided on the second side 14b of the lid 14. The overcoat layer 40 can include the same or similar materials as the overcoat layer 22. The overcoat layer 40 can function as a passivation layer to protect the conductive trace 18a of the inductor 18 and/or as an insulator between neighboring lines of the conductive trace 18a. The overcoat layer 40 can include any suitable organic or dielectric material. For example, the overcoat layer 40 can include polyimide, fluoropolymer, silicon oxide, silicon nitride, polytetrafluoroethylene (PTFE), polyphenylene sulfide (e.g., fortron manufactured by Fortron Industries LLC), benzocyclobutene (BCB), SU8 (e.g., bisphenol A novolac epoxy dissolved in an organic solvent), or acrylate-based polymer. In some embodiments, the overcoat layer 40 can include a material (e.g., a ceramic) with a relatively high dielectric constant. For example, the overcoat layer 40 can include titanium oxide (e.g., titanium dioxide (TiO₂)), calcium titanate (e.g., CaTiO₃), strontium titanate (e.g., SrTiO₃), barium strontium titanate (e.g., Ba_{0.5}Sr_{0.5}TiO₃) or the like material. In some embodiments, the relatively high dielectric constant material can be blended with a polymer to define a polymer-ceramic composite. In some embodiments, the overcoat layer 40 can be a redistribution layer (RDL) that includes electrical routings therein.

The acoustic wave device 4 can include a shield layer 34 positioned between the resonator 12 and the inductor 18. In some embodiments, the shield layer 34 can be formed on the first side 14a of the lid 14. The shield 34 can be electrically coupled to the substrate 10 by way of an interconnect structure 20. In some embodiments, the shield 34 can be grounded at least partially through the interconnect structure 20. In some embodiments, the shield layer 34 can be omitted. For example, when the lid 14 has a significant thickness (e.g., a thickness in a range between about 30 microns and about 150 microns or about 50 μm and about 150 μm) that provides a sufficient distance between the resonator 12 and the inductor 18 so as to prevent or mitigate interference between the resonator 12 and the inductor 18, the shield layer 34 may be less beneficial.

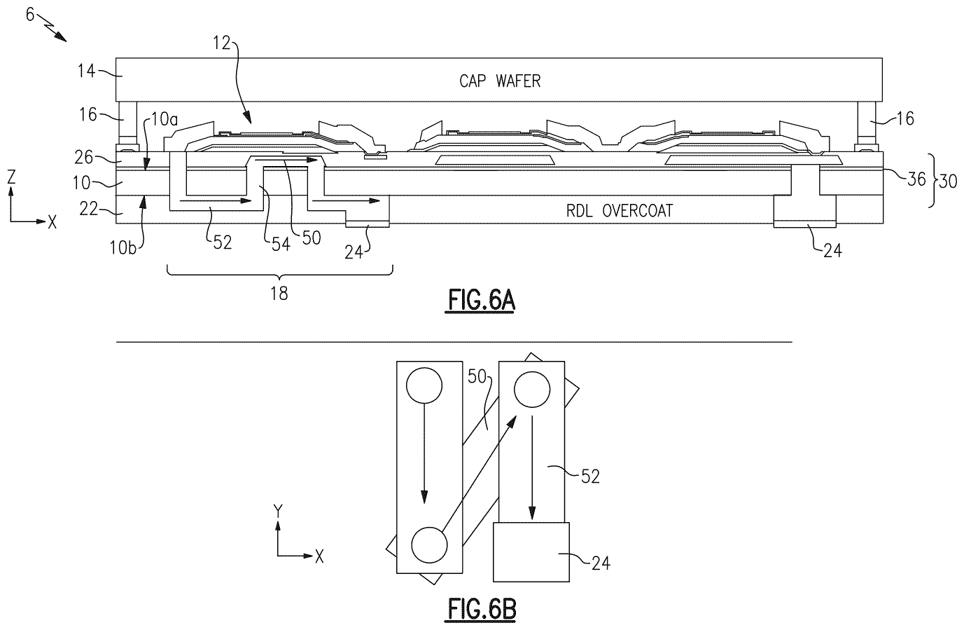

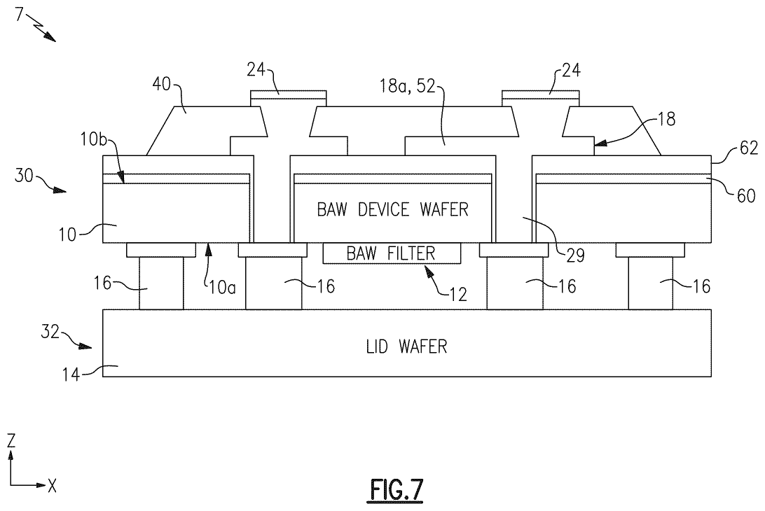

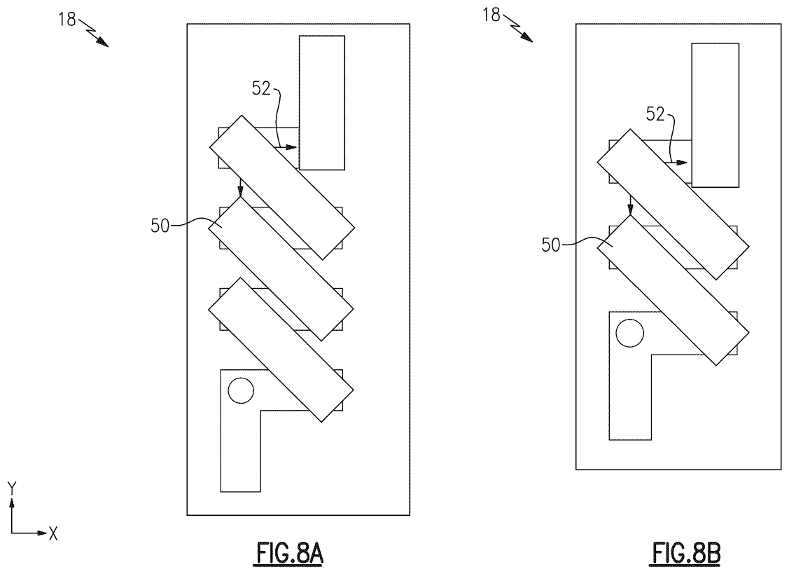

FIGS. 1A-4B show inductors that are formed on a surface of a substrate or a lid. Such inductors of FIGS. 1A-4B can be referred to as two-dimensional (2D) inductors. In FIGS. 5A-6B, inductors that include portions that are disposed on more than one surface of the substrate or the lid are disclosed. Such inductors of FIGS. 5A-6B can be referred to as three-dimensional (3D) inductors.

FIG. 5A is a schematic cross-sectional side view of an acoustic wave device 5 according to an embodiment. FIG. 5B is a top plan view of an inductor 18 formed with a lid 14 of the acoustic wave device 5 of FIG. 5A. Unless otherwise noted, the components of the acoustic wave device 5 shown in FIGS. 5A and 5B may be structurally and/or functionally the same as or generally similar to like components of the acoustic wave devices 1-4 of FIGS. 1A-4B. The acoustic wave device 5 can include a substrate 10, an acoustic wave resonator 12, a lid 14 coupled to the substrate by way of a coupler (e.g., a seal ring 16), and the inductor 18 formed with the lid 14. The acoustic wave device 5 can also include an interconnect structure 20 that extends between the substrate 10 and the lid 14, and a terminal 24 that is configured to electrically connect the acoustic wave device 5 to an external device or a circuit board (not shown).

The lid 14 and the inductor 18 can together define an inductor integrated lid 32. The inductor 18 can include a first portion 50 formed on a first side 14a of the lid 14, a second portion 52 formed on the second side 14b of the lid 14, and a third portion 54 that extends through a thickness of the lid 14. In some embodiments, a spacing between adjacent lines of the first portion 50, a spacing between adjacent lines of the second portion 52, and/or a spacing between adjacent lines of the third portion 54 can function as the spacing between the lines of the conductive trace 18a in the 2D inductors disclosed herein. Therefore, the 3D inductors can operate based on the same or similar principles as the 2D inductors. In some embodiments, the first portion 50 and the second portion 52 can each define an inductor (e.g., a coil inductor) and the third portion 54 can electrically connect the first and second portions 50, 52. Therefore, multiple 2D inductors on different sides of the lid 14 can be connected in some embodiments.

FIG. 6A is a schematic cross-sectional side view of an acoustic wave device 6 according to an embodiment. FIG. 6B is a bottom plan view of an inductor 18 formed with a substrate 10 of the acoustic wave device 6 of FIG. 6A. Unless otherwise noted, the components of the acoustic wave device 6 shown in FIGS. 6A and 6B may be structurally and/or functionally the same as or generally similar to like components of the acoustic wave devices 1-5 of FIGS. 1A-5B.

The substrate 10 and the inductor 18 can together define an inductor integrated substrate 30. The inductor 18 can include a first portion 50 formed on a first side 10a of the substrate 10, a second portion 52 formed on the second side 10b of the substrate 10, and a third portion 54 that extends through a thickness of the substrate 10. The first portion 50 can include a metal layer. In some embodiments, the metal layer that defines the first portion 50 can be embedded in the passivation layer 26. In some embodiments, a portion of the passivation layer 26 and a portion of the trap rich layer 36 can be positioned between the substrate 10 and the first portion 50.

The two-dimensional (2D) inductors can be relatively easy to manufacture. The three-dimensional (3D) inductors can provide a greater inductance for a given area as compared to the 2D inductors. Any suitable principles and advantages of inductors disclosed herein can be implemented in a packaged acoustic wave device die. In some embodiments, the 2D and 3D inductors can be implemented in a packaged acoustic wave die. In some embodiments, two or more 2D inductors can be implemented in a packaged acoustic wave die. Also, an acoustic wave resonator can include both the inductor integrated substrate 30 and the inductor integrated lid 32.

FIG. 7 is a schematic cross-sectional side view of an acoustic wave device 7 according to an embodiment. Unless otherwise noted, the components of the acoustic wave device 7 shown in FIG. 7 may be structurally and/or functionally the same as or generally similar to like components of the acoustic wave devices 1-6 of FIGS. 1A-6B. The acoustic wave device 7 can include an inductor integrated substrate 30 and an inductor integrated lid 32 (an inductor not illustrated) that are coupled to one another. The resonator 12 (e.g., a BAW resonator) can be positioned between the inductor integrated substrate 30 and the inductor integrated lid 32.

The inductor integrated substrate 30 can include the substrate 10 and the inductor 18. A portion of the inductor that is positioned on the second side 10b of the substrate 10 can be the conductive trace 18a or the second portion 52 disclosed herein. In some embodiments, the inductor integrated substrate 30 can also include one or more additional layers between the conductive trace 18a or the second portion 52 and the substrate 10. For example, the additional layers can include a trap rich layer 60 and a dielectric layer 62. In some embodiments, the trap rich layer 60 can include polysilicon. The trap rich layer can be deposited by way of, for example, chemical vapor deposition (CVD), such as plasma-enhanced chemical vapor deposition (PECVD) at a temperature in a range between, for example, 100° C. and 400° C. or low-pressure chemical vapor deposition (LPCVD) at a temperature in a range between, for example, 500° C. and 700° C. In some embodiments, the trap rich layer 60 can be a low temperature trap rich layer that is deposited at a temperature less than about 300° C., less than about 250° C., or less than about 200° C. In some embodiments, the dielectric layer 62 can include a silicon oxide underlayer (e.g., silicon dioxide layer) or a polyimide redistribution underlayer. The dielectric layer 62 can be provided for process reasons in conjunction with copper plating for forming the via 29 and/or the inductor 18. In some embodiments, the trap rich layer 60 and/or dielectric layer 62 can help reduce nonlinearities such as the third-order distortion (IMD3) and H2. Some additional layers such as a seed layer (not shown) can be provided for, for example, a plating process.

Though the illustrated embodiments disclosed herein may show one inductor on a side of a lid or a substrate, there can be two or more inductors formed on a side of the lid or a substrate. For example, two or more inductors can be formed on a first side 14a of the lid 14, two or more inductors can be formed on a second side 14b of the lid 14, two or more inductors can be formed on a first side 10a of the substrate 10, or two or more inductors can be formed on a second side 10b of the substrate 10. There may be any suitable number of inductors included in a single acoustic wave device.

FIGS. 8A and 8B are plan views of three-dimensional (3D) inductors that can be implemented in acoustic wave devices in accordance with various embodiments disclosed herein. The inductor 18 shown in FIG. 8A includes three segments of the first portion 50 and four segments of the second portion 52. The inductor 18 shown in FIG. 8B includes two segments of the first portion 50 and three segments of the second portion 52. The segments of the first portion 50 and the second portion 52 can be electrically coupled by a third portion 54 (see FIGS. 5A and 6A). The inductor 18 of FIG. 8A can provide three turns and the inductor 18 of FIG. 8B can provide two turns of the conductive material for providing inductance. In some embodiments, lateral dimensions surrounding the inductor 18 of FIG. 8A can be about 315 microns×135 microns, and lateral dimensions surrounding the inductor 18 of FIG. 8B can be about 225 microns×135 microns. Depending on the dimensions of the first to third portions 50-54, the lateral dimensions surrounding the inductor 18 of FIG. 8A and lateral dimensions surrounding the inductor 18 of FIG. 8B can be different. In some embodiments, the lateral dimensions of the inductors 18 of FIGS. 8A and 8B can be smaller than the dimensions disclosed herein.

The acoustic wave devices disclosed herein can be formed in any suitable manner. For example, the inductor 18 can be formed with the substrate 10 and/or the lid 14 before coupling the substrate 10 and the lid 14. In some embodiments, a method of forming an acoustic wave device can include providing a resonator 12 on a substrate 10 and coupling an inductor integrated lid 32 to the substrate 10 such that the resonator 12 is positioned between the substrate 10 and the inductor integrated lid 32. The inductor integrated lid has a first side facing the substrate and a second side opposite the first side. The method can further include forming an inductor in the inductor integrated lid. At least a portion of the inductor can be disposed on the first side or the second side.

In some embodiments, a method of forming an acoustic wave device can include forming an inductor with a substrate that has a first side and a second side opposite the first side. At least a portion of the inductor is disposed on the second side of the substrate. The method can also include providing a resonator on the first side of the substrate. At least a portion of the resonator is positioned over the inductor. The method can further include further providing an overcoat layer over the inductor on the second side of the substrate. The inductor can be a spiral inductor formed on the second side of the substrate. In some embodiments, the inductor can include a first portion formed on the first side of the substrate, a second portion formed on the second side of the substrate, and a third portion formed through a thickness of the substrate.

Though the Figures may show bulk acoustic wave (BAW) resonators as examples of the resonator 12, the acoustic wave devices disclosed herein can implement other types of resonators, such as a surface acoustic wave resonator. The acoustic wave devices disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

FIG. 9 is a schematic diagram of an example of an acoustic wave ladder filter 120. The acoustic wave ladder filter 120 can be a transmit filter or a receive filter. The acoustic wave ladder filter 120 can be a band pass filter arranged to filter a radio frequency signal. The acoustic wave filter 120 includes series resonators R1, R3, R5, R7, and R9 and shunt resonators R2, R4, R6, and R8 coupled between a radio frequency input/output port RF_{I/O} and an antenna port ANT. The radio frequency input/output port RF_{I/O} can be a transmit port in a transmit filter or a receive port in a receive filter. An acoustic wave ladder filter can include any suitable number of series resonators and any suitable number of shunt resonators.

An acoustic wave filter can be arranged in any other suitable filter topology, such as a lattice topology or a hybrid ladder and lattice topology. An acoustic wave device in accordance with any suitable principles and advantages disclosed herein can be implemented in a band pass filter. In some other applications, An acoustic wave device in accordance with any suitable principles and advantages disclosed herein can be implemented in a band stop filter.

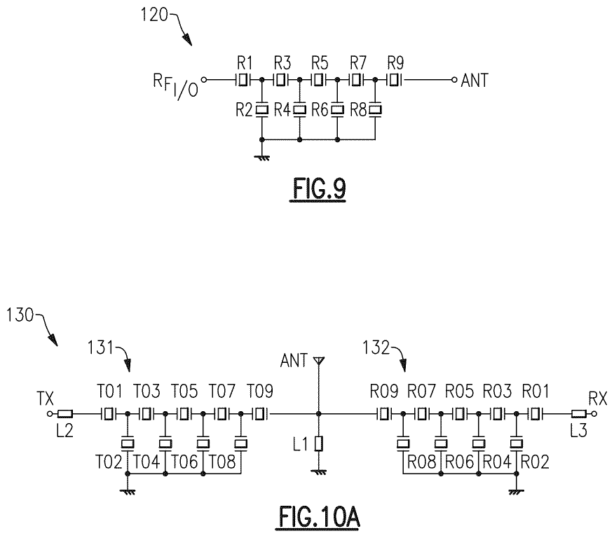

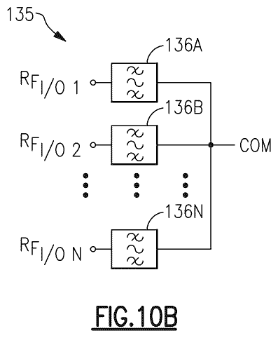

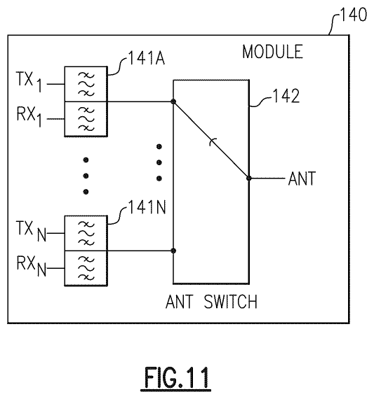

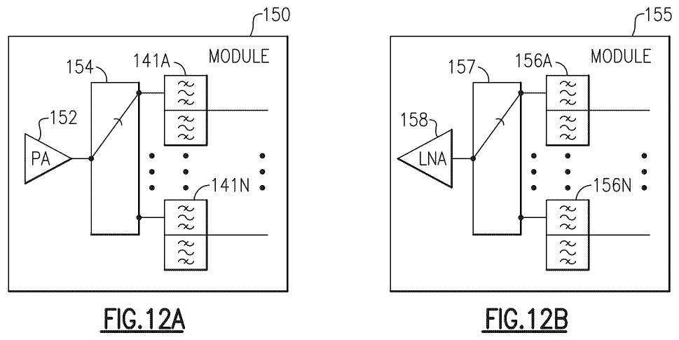

FIG. 10A is a schematic diagram of an example of a duplexer 130. The duplexer 130 includes a transmit filter 131 and a receive filter 132 coupled to each other at an antenna node ANT. A shunt inductor L1 can be connected to the antenna node ANT. The transmit filter 131 and the receive filter 132 are both acoustic wave ladder filters in the duplexer 130.

The transmit filter 131 can filter a radio frequency signal and provide a filtered radio frequency signal to the antenna node ANT. A series inductor L2 can be coupled between a transmit input node TX and the acoustic wave resonators of the transmit filter 131. The illustrated transmit filter 131 includes acoustic wave resonators T01 to T09. One or more of these resonators can be a bulk acoustic wave resonator in accordance with any suitable principles and advantages disclosed herein. The illustrated receive filter includes acoustic wave resonators R01 to R09. The receive filter can filter a radio frequency signal received at the antenna node ANT. A series inductor L3 can be coupled between the resonator and a receive output node RX. The receive output node RX of the receive filter provides a radio frequency receive signal. The shunt inductor L1, the series inductor L2, and/or the series inductor L3 can be implemented in accordance with any suitable principles and advantages disclosed herein

FIG. 10B is a schematic diagram of a multiplexer 135 that includes an acoustic wave filter according to an embodiment. The multiplexer 135 includes a plurality of filters 136A to 136N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 136A, 136B, and 136N is coupled between the common node COM and a respective input/output node RF_{I/O1}, RF_{I/O2}, and RF_{I/ON}.

In some instances, all filters of the multiplexer 135 can be receive filters. According to some other instances, all filters of the multiplexer 135 can be transmit filters. In various applications, the multiplexer 135 can include one or more transmit filters and one or more receive filters. Accordingly, the multiplexer 135 can include any suitable number of transmit filters and any suitable number of receive filters. Each of the illustrated filters can be band pass filters having different respective pass bands.

The multiplexer 135 is illustrated with hard multiplexing with the filters 136A to 136N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 136A is an acoustic wave filter having a first pass band and arranged to filter a radio frequency signal. The first filter 136A can include one or more bulk acoustic wave resonators according to any suitable principles and advantages disclosed herein. A second filter 136B has a second pass band. In certain instances, the common node COM of the multiplexer 135 is arranged to receive a carrier aggregation signal including at least a first carrier associated with the first passband of the first filter 136A and a second carrier associated with the second passband of the second filter 136B.

The acoustic wave devices with one or more integrated inductors disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 11-13 are schematic block diagrams of illustrative packaged modules according to certain embodiments. Certain example packaged modules include one or more radio frequency amplifiers, such as one or more power amplifiers and/or one or more low noise amplifiers. Any suitable combination of features of these modules can be implemented with each other. While duplexers are illustrated in some examples packaged modules, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 11 is a schematic block diagram of a module 140 that includes duplexers 141A to 141N and an antenna switch 142. One or more filters of the duplexers 141A to 141N can include any suitable number of bulk acoustic wave resonators. Any suitable number of duplexers 141A to 141N can be implemented. The antenna switch 142 can have a number of throws corresponding to the number of duplexers 141A to 141N. The antenna switch 142 can electrically couple a selected duplexer to an antenna port of the module 140.

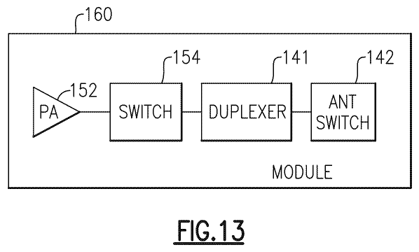

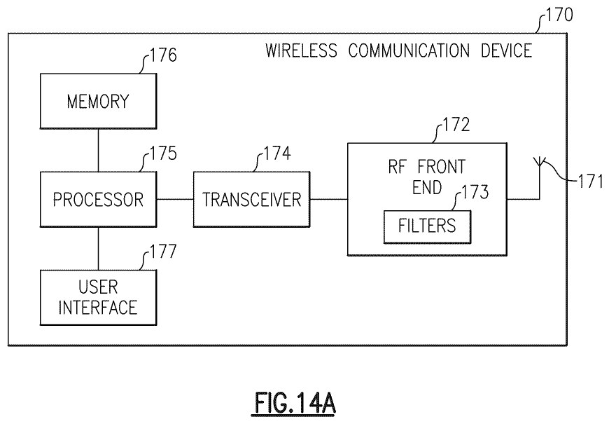

FIG. 12A is a schematic block diagram of a module 150 that includes a power amplifier 152, a radio frequency switch 154, and duplexers 141A to 141N in accordance with one or more embodiments. The power amplifier 152 can amplify a radio frequency signal. The radio frequency switch 154 can be a multi-throw radio frequency switch. The radio frequency switch 154 can electrically couple an output of the power amplifier 152 to a selected transmit filter of the duplexers 141A to 141N. One or more filters of the duplexers 141A to 141N can include any suitable number of bulk acoustic wave resonators. Any suitable number of duplexers 141A to 141N can be implemented.

FIG. 12B is a schematic block diagram of a module 155 that includes filters 156A to 156N, a radio frequency switch 157, and a low noise amplifier 158 according to an embodiment. One or more filters of the filters 156A to 156N can include any suitable number of acoustic wave devices in accordance with any suitable principles and advantages disclosed herein. Any suitable number of filters 156A to 156N can be implemented. The illustrated filters 156A to 156N are receive filters. In some embodiments (not illustrated), one or more of the filters 156A to 156N can be included in a multiplexer that also includes a transmit filter. The radio frequency switch 157 can be a multi-throw radio frequency switch. The radio frequency switch 157 can electrically couple an output of a selected filter of filters 156A to 156N to the low noise amplifier 158. In some embodiments (not illustrated), a plurality of low noise amplifiers can be implemented. The module 155 can include diversity receive features in certain applications.

FIG. 13 is a schematic block diagram of a module 160 that includes a power amplifier 152, a radio frequency switch 154, and a duplexer 141 that includes an acoustic wave device in accordance with one or more embodiments, and an antenna switch 142. The module 160 can include elements of the module 140 and elements of the module 150.

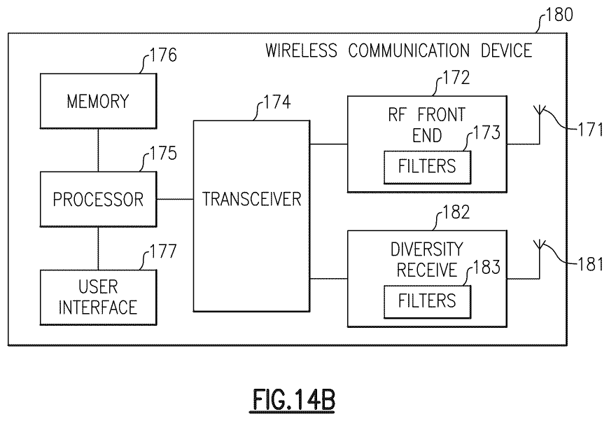

One or more filters with any suitable number of bulk acoustic devices can be implemented in a variety of wireless communication devices. FIG. 14A is a schematic block diagram of a wireless communication device 170 that includes a filter 173 with one or more bulk acoustic wave resonators in accordance with any suitable principles and advantages disclosed herein. The wireless communication device 170 can be any suitable wireless communication device. For instance, a wireless communication device 170 can be a mobile phone, such as a smart phone. As illustrated, the wireless communication device 170 includes an antenna 171, a radio frequency (RF) front end 172 that includes filter 173, an RF transceiver 174, a processor 175, a memory 176, and a user interface 177. The antenna 171 can transmit RF signals provided by the RF front end 172. The antenna 171 can provide received RF signals to the RF front end 172 for processing.

The RF front end 172 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 172 can transmit and receive RF signals associated with any suitable communication standards. Any of the acoustic wave devices disclosed herein can be implemented in filters 173 of the RF front end 172.

The RF transceiver 174 can provide RF signals to the RF front end 172 for amplification and/or other processing. The RF transceiver 174 can also process an RF signal provided by a low noise amplifier of the RF front end 172. The RF transceiver 174 is in communication with the processor 175. The processor 175 can be a baseband processor. The processor 175 can provide any suitable base band processing functions for the wireless communication device 170. The memory 176 can be accessed by the processor 175. The memory 176 can store any suitable data for the wireless communication device 170. The processor 175 is also in communication with the user interface 177. The user interface 177 can be any suitable user interface, such as a display.

FIG. 14B is a schematic diagram of a wireless communication device 180 that includes filters 173 in a radio frequency front end 172 and second filters 183 in a diversity receive module 182. The wireless communication device 180 is like the wireless communication device 170 of FIG. 14A, except that the wireless communication device 180 also includes diversity receive features. As illustrated in FIG. 14B, the wireless communication device 180 includes a diversity antenna 181, a diversity module 182 configured to process signals received by the diversity antenna 181 and including filters 183, and a transceiver 174 in communication with both the radio frequency front end 172 and the diversity receive module 182. One or more of the second filters 183 can include a acoustic wave device in accordance with any suitable principles and advantages disclosed herein.

Acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

An acoustic wave filter including any suitable combination of features disclosed herein can be arranged to filter a radio frequency signal in a fifth generation (5G) New Radio (NR) operating band within Frequency Range 1 (FR1). A filter arranged to filter a radio frequency signal in a 5G NR operating band can include one or more devices of any of the stacked device arrangements disclosed herein. FR1 can be from 410 MHz to 7.125 GHZ, for example, as specified in a current 5G NR specification. One or more acoustic wave filters in accordance with any suitable principles and advantages disclosed herein can be arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as die and/or acoustic wave components and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a substrate;
a lid having a first side facing the substrate and a second side opposite the first side, the lid coupled to the substrate;
a resonator positioned between the substrate and the lid; and
an inductor formed with the lid, the inductor at least partially positioned over a portion of the resonator.

2. The acoustic wave device of claim 1 wherein the substrate and the lid are coupled by a seal ring, the substrate, the lid, and the seal ring together define a hermetic cavity in which the resonator is positioned.

3. The acoustic wave device of claim 1 wherein the resonator is a bulk acoustic wave resonator.

4. The acoustic wave device of claim 1 wherein the inductor is a spiral inductor formed on the first side of the lid.

5. The acoustic wave device of claim 1 wherein the inductor is a spiral inductor formed on the second side of the lid.

6. The acoustic wave device of claim 5 further comprising an overcoat layer over the inductor, wherein the overcoat layer includes a low dielectric loss polymeric material that has a dielectric loss less than 0.01.

7. The acoustic wave device of claim 6 wherein the low dielectric loss polymeric material is polyimide, fluoropolymer, polyphenylene sulfide, or benzocyclobutene.

8. The acoustic wave device of claim 7 wherein the overcoat layer includes titanium oxide, calcium titanate, strontium titanate, or barium strontium titanate blended with the low dielectric loss polymeric material that defines a composite material and the composite material has a dielectric constant greater than 5.

9. The acoustic wave device of claim 1 wherein the inductor includes a first portion formed on the first side of the lid, a second portion formed on the second side of the lid, and a third portion formed through a thickness of the lid.

10. The acoustic wave device of claim 1 further comprising a second inductor formed with the substrate and a shield layer positioned between the second inductor and the resonator.

11. The acoustic wave device of claim 1 wherein the substrate and the lid are spaced apart in a range between 5 microns and 50 microns.

12. The acoustic wave device of claim 1 wherein a thickness of the lid is in a range between 30 microns and 150 microns.

13. The acoustic wave device of claim 1 wherein the inductor includes copper, aluminum, gold, silver, tungsten, molybdenum, ruthenium, iridium, or platinum.

14. The acoustic wave device of claim 1 wherein the lid includes silicon, gallium arsenide, silicon carbide, sapphire, quartz, glass, ceramics, polymers, oxides, or nitrides.

15. The acoustic wave device of claim 1 further comprising an interconnect that connects the substrate and the inductor.

16. The acoustic wave device of claim 1 wherein the substrate includes a terminal configured to electrically connect the acoustic wave device to an external device or a circuit board.

17. A method of forming an acoustic wave device, the method comprising:
providing a resonator on a substrate; and
coupling an inductor integrated lid to the substrate such that the resonator is positioned between the substrate and the inductor integrated lid, the inductor integrated lid having a first side facing the substrate and a second side opposite the first side.

18. The method of claim 17 further comprising forming an inductor in the inductor integrated lid, wherein at least a portion of the inductor is disposed on the first side or the second side.

19. The method of claim 18 wherein the inductor includes a first portion formed on the first side of the inductor integrated lid, a second portion formed on the second side of the inductor integrated lid, and a third portion formed through a thickness of the inductor integrated lid.

20. An acoustic wave device comprising:
a substrate;
an inductor integrated lid having a first side facing the substrate, a second side opposite the first side, and an inductor, the inductor integrated lid coupled to the substrate; and
a resonator positioned between the substrate and the inductor integrated lid, the inductor at least partially positioned over a portion of the resonator.
